(19) United States
(12) Patent Application Publication
(10) Pub. No.: US 2010/0243471 A1
(43) Pub. Date: Sep. 30, 2010

(54) COMPOSITION, METHOD AND PROCESS FOR POLISHING A WAFER

(75) Inventors: Naichao Li, Woodbury, MN (US); John J. Gagliardi, Hudson, WI (US); Philip G. Clark, Eden Prairie, MN (US); Patricia M. Savu, Maplewood, MN (US)

Correspondence Address: 3M INNOVATIVE PROPERTIES COMPANY, PO BOX 33427, ST. PAUL, MN, 55133-3427, US

(73) Assignee: 3M INNOVATIVE PROPERTIES COMPANY, Saint Paul, MN (US)

(21) Appl. No.: 12/739,804

(22) PCT Filed: Aug. 25, 2008
(86) PCT No.: PCT/US2008/074199

§ 371 Date: Apr. 26, 2010

Related U.S. Application Data
(60) Provisional application No. 60/984,217, filed on Oct. 31, 2007.

(51) Int. Cl. C09K 13/00; H01L 21/302; C25F 3/30

(52) U.S. Cl. 205/662; 205/674; 205/684

(57) ABSTRACT

A composition for use in polishing a wafer is disclosed. The composition includes an aqueous solution of initial components substantially free of loose abrasive particles and having a pH in the range of about 2 to 7, the aqueous solution including at least one polyelectrolyte and a surfactant. In certain embodiments, the wafer polishing composition can be adjusted to control cut rate and selectivity for modifying semiconductor wafers using a fixed abrasive Chemical Mechanical Polishing (CMP) process. Also disclosed is a CMP method and a process for polishing a wafer using the polishing composition.

### FIELD

The present disclosure relates generally to a composition for modifying an exposed surface of a semiconductor wafer. More particularly, the disclosure relates to a composition that can be adjusted to control cut rate and selectivity in methods for modifying semiconductor wafers using a fixed abrasive chemical-mechanical planarization process.

### BACKGROUND

During integrated circuit manufacture, semiconductor wafers used in semiconductor fabrication typically undergo numerous processing steps, including deposition, patterning, and etching steps. Details of these manufacturing steps for semiconductor wafers are reported by Tonshoff et al., “Abrasive Machining of Silicon”, published in the Annals of the International Institution for Production Engineering Research, (Volume 39/2/1990), pp. 621-635. In each manufacturing step, it is often necessary or desirable to modify or refine an exposed surface of the wafer in order to prepare the wafer for subsequent fabrication or manufacturing steps. For example, semiconductor wafers having shallow trench isolation (STI) structures for Dynamic Random Access Memory (DRAM) applications often require planarization of the dielectric material prior to further processing.

One method of modifying or refining exposed surfaces of wafers employs processes that treat a wafer surface with a slurry containing a plurality of loose abrasive particles dispersed in a liquid. Typically this slurry is applied to a polishing pad and the wafer surface is then ground or moved against the pad in order to remove or take off material from the wafer surface. Generally, the slurry also contains agents that chemically react with the wafer surface. This type of process is commonly referred to as a chemical-mechanical planarization (CMP) process.

One limitation of CMP slurries, however, is that the slurry abrasive process must be carefully monitored in order to achieve a desired wafer surface topography. A second limitation is the mess associated with loose abrasive slurries. Another limitation is that the slurries generate a large number of particles that must be removed from the surface of the wafer and disposed of following wafer treatment. Handling and disposal of these slurries generates additional processing costs for the semiconductor wafer fabricator.

An alternative to CMP slurry methods uses an abrasive article to modify or refine a semiconductor surface. A CMP process that uses abrasive articles has been reported, for example, by Bruxvoort et al. in U.S. Pat. No. 5,958,794 and by Kaisaki et al. in U.S. Pat. No. 6,194,317. The reported abrasive articles have a textured abrasive surface that includes abrasive particles dispersed in a binder. In use, the abrasive article is contacted with a semiconductor wafer surface, often in the presence of a fluid or liquid to provide a planar, uniform wafer surface. Use of an abrasive article overcomes some limitations associated with CMP slurries.

### SUMMARY

The present disclosure relates generally to compositions and methods for modifying an exposed surface of a semiconductor wafer. More particularly, the present disclosure relates to compositions that can be adjusted to control cut rate and selectivity in methods for modifying semiconductor wafers using a fixed abrasive CMP process. In some embodiments, the disclosure exploits the advantages afforded by the use of abrasive articles to modify surfaces of patterned semiconductor wafers.

In one aspect, the present disclosure relates to a working liquid comprising an aqueous solution of initial components substantially free of loose abrasive particles, the components including water, a polyelectrolyte, and a surfactant, and the working liquid exhibiting a pH from about 2 to 7. In exemplary embodiments, the working liquid is useful in modifying a surface of a wafer suited for fabrication of a semiconductor device, wherein the surfactant is present in an amount effective to obtain an oxide removal rate of at least about 200 angstroms per minute and the polyelectrolyte is present in an amount effective to obtain an oxide to nitride selectivity of at least about 10 when used with a fixed abrasive article for chemical mechanical planarization of a DRAM STI wafer. In certain embodiments, the working liquid may additionally include a complexing agent, which may be a multidentate acidic complexing agent such as an amino acid or a dipeptide formed from an amino acid.

In another aspect, the present disclosure relates to a method of modifying a surface of a wafer suited for fabrication of a semiconductor device, the wafer comprising at least a first material having a surface etched to form a pattern, a second material deployed over at least a portion of the surface of the first material, and a third material deployed over at least a portion of the surface of the second material. The method includes providing the wafer and providing relative motion between the wafer and a plurality of three-dimensional abrasive composites in the presence of a working liquid while the third material is in contact with the plurality of abrasive composites until an exposed surface of the wafer is planar and comprises at least one area of exposed third material and one area of exposed second material.

In exemplary embodiments, the abrasive composites are fixed to the surface of an abrasive article. In additional exemplary embodiments, the abrasive composites comprise a plurality of abrasive particles fixed and dispersed in a binder. In further exemplary embodiments, the working liquid comprises an aqueous solution of initial components substantially free of loose abrasive particles, the components including water, a polyelectrolyte, and a surfactant, and the working liquid exhibiting a pH from about 2 to 7. In certain exemplary embodiments, the working liquid is useful in modifying a surface of a wafer suited for fabrication of a semiconductor device, wherein the surfactant is present in an amount effective to obtain an oxide removal rate of at least about 200 angstroms per minute and the polyelectrolyte is present in an amount effective to obtain an oxide to nitride selectivity of at least about 10 when used with a fixed abrasive article for chemical mechanical planarization of a DRAM STI wafer.

In another aspect, the present disclosure provides a method for polishing a wafer by providing a wafer comprising a first region comprising a dielectric material, such as silicon dioxide, and a second region comprising a barrier material, such as silicon nitride. In certain exemplary embodiments, the wafer is contacted with a three-dimensional, textured, fixed abrasive article comprising a plurality of abrasive particles and a binder, while providing relative motion between the wafer and the abrasive article while the second region is in contact with the plurality of abrasive composites in the presence of an aqueous solution. In certain exemplary embodiments, the aqueous solution exhibits a pH in the range of about 2 to 7, and comprises at least one polyelectrolyte and at least one surfactant. In further exemplary embodiments, the surfactant is present in an amount effective to obtain an oxide removal rate of at least about 200 angstroms per minute and the polyelectrolyte is present in an amount effective to obtain an oxide to nitride selectivity of at least about 10 when used with a fixed abrasive article for chemical mechanical planarization of a DRAM STI wafer.

In another aspect, the present disclosure provides a wafer planarization process comprising an aqueous working fluid according to the present disclosure and a three-dimensional, textured, fixed abrasive article comprising a plurality of abrasive particles and a binder. In some exemplary processes, the abrasive article comprises precisely shaped abrasive composites. In certain exemplary embodiments, the aqueous solution exhibits a pH in the range of about 2 to 7, and comprises at least one polyelectrolyte and at least one surfactant. In further exemplary embodiments, the surfactant is present in an amount effective to obtain an oxide removal rate of at least about 200 angstroms per minute and the polyelectrolyte is present in an amount effective to obtain an oxide to nitride selectivity of at least about 10 when used with a fixed abrasive article for chemical mechanical planarization of a DRAM STI wafer.

In certain exemplary embodiments, the compositions and methods of the present disclosure unexpectedly enhance the performance of chemical mechanical planarization processes that use fixed abrasives rather than polishing pads and slurries.

The above summary is not intended to describe each disclosed embodiment or every implementation of the invention. The Figures, Detailed Description, and Claims that follow more particularly exemplify illustrative embodiments.

### BRIEF DESCRIPTION OF THE DRAWINGS

FIG. 1 is a schematic cross-sectional view of a portion of a structured wafer before surface modification; and

FIG. 2 is a schematic cross-sectional view of the structured wafer of FIG. 1 after surface modification using the present disclosure.

These figures, which are idealized, are not to scale and are intended to be merely illustrative of certain embodiments of the invention and non-limiting.

### DETAILED DESCRIPTION

In the context of the present disclosure:

“abrasive composite” refers to one of a plurality of shaped bodies that collectively provide a textured, three-dimensional abrasive article comprising abrasive particles and a binder, wherein the abrasive particles may be in the form of abrasive agglomerates;

“fixed abrasive article” refers to an integral abrasive article that is substantially free of unattached abrasive particles except as may be generated during the planarization process;

“interact” with the wafer refers to an interaction that can be a polar interaction (e.g., van der Waals forces) or a chemical reaction;

“polyelectrolyte” refers to polymers and copolymers having at least one ionizable functional group, and include polymers and copolymers of methacrylic acid, esters of acrylic acid and/or methacrylic acid having at least one ionizable functional group;

“precisely shaped abrasive composite” refers to an abrasive composite having a molded shape that is the inverse of the mold cavity that is retained after the composite has been removed from the mold, wherein the composite can be substantially free of abrasive particles protruding beyond the exposed surface of the shape before the abrasive article has been used, as described by Pieper et al. in U.S. Pat. No. 5,152,917;

“selectivity” refers to the ratio of the rate at which a first material (e.g. a dielectric material such as silicon dioxide) can be removed from a wafer surface to the rate at which a second material (e.g., a barrier material such as silicon nitride) can be removed from the wafer surface during a CMP process;

“surfactant” means a surface active chemical compound, including, for example, molecular surfactants, oligomeric surfactants, polymeric surfactants, nonionic surfactants, anionic surfactants, cationic surfactants, zwitterionic surfactants, and fluorochemical surfactants.

“textured abrasive article” refers to an abrasive article having raised portions and recessed portions in which at least the raised portions contain abrasive particles and binder;

“three-dimensional abrasive article” refers to an abrasive article having numerous abrasive particles extending throughout at least a portion of its thickness such that removing some of the particles during planarization exposes additional abrasive particles capable of performing the planarization function; and

“wafer” refers to a semiconductor wafer in the form of a blank wafer (i.e., a wafer prior to processing for the purpose of adding topographical features such as metallized and insulating areas) or a processed wafer (i.e., a wafer after it has been subjected to one or more processing steps to add topographical features to the wafer surface).

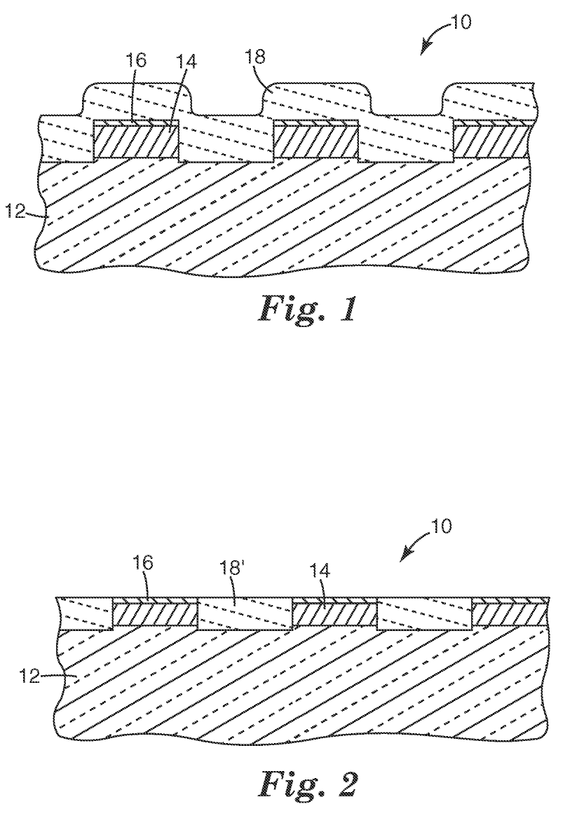

Various embodiments of the disclosure will now be described with particular reference to the Drawings. FIG. 1 is a representative view of a patterned wafer 10 suitable for use in the process according to the present disclosure. For clarity, known features such as doped regions, active devices, epitaxial layers, carrier and field oxide layers have been omitted. Wafer 10 has a base 12 and a plurality of shallow trench isolation structures 14. The shallow trench isolation structures are typically formed by depositing and patterning silicon nitride to form a mask layer 16 on the surface of the wafer, and then forming trenches using any of the etching processes known to those skilled in the art.

A dielectric layer 18 is deposited over the surface of the shallow trench isolation structures and into the spaces between the shallow trench isolation structures. A variety of dielectric materials may be used, such as, for example, silicon dioxide. As used in the context of the present disclosure, “silicon dioxide” refers to silicon dioxide as well as doped variants of silicon dioxide, such as, for example, fluorine, boron, and/or phosphorous doped silicon dioxide.

A portion of the dielectric layer 18 is then removed using the CMP process of the present disclosure to form the desired pattern illustrated in FIG. 2. As shown in FIG. 2, the polished dielectric material 18′ and mask layer 16 form a generally flat surface. The mask layer functions as a stop layer for the CMP process that protects the shallow trench isolation structure 14 from exposure to the CMP processing.

CMP machines useful with the processes of the present disclosure are commercially available and known to those skilled in the art. An exemplary CMP machine is commercially obtained from Applied Materials, Santa Clara, Calif. and is marketed under the trade designation Reflexion™ web polisher. The fixed abrasive article may be mounted to either the CMP machine platen or carrier, and the wafer to be polished may be mounted to the corresponding CMP machine carrier or platen. Preferably, the fixed abrasive article is mounted to the platen and the wafer is mounted to the carrier.

Processing conditions employed with the CMP machines include carrier and platen rotational speeds between about 5 to 10,000 revolutions per minute (RPM). Preferably, rotational speeds of about 10 to 1,000 RPM are employed. More preferably, rotational speeds are selected to be between about 10 to 250 RPM. Most preferably, rotational speeds between about 10 to 100 RPM are used. In some embodiments, the platen and carrier are rotated in the same direction. In other embodiments, the platen and carrier are rotated in opposite direction.

Polishing pressure on the wafer, either actual or set point, may be between about 0.1 to 20 psi (0.7 to 138 kPa), preferably between about 1 to 10 psi (6.9 to 69 kPa) and more preferably between about 2 to 6 psi (13.8 to 41.4 kPa).

Exemplary CMP machines useful for the processes and methods of the present disclosure may be fitted with a fixed abrasive polishing article as reported, for example, by Bruxvoort et al. and by Kaisaki et al. referenced above. The fixed abrasive article is used to polish the exposed surface of a wafer in the presence of a liquid medium (i.e., working liquid).

### Fixed Abrasive Articles

Exemplary fixed abrasive articles useful in the CMP process of the present disclosure include those disclosed by Bruxvoort et al. in U.S. Pat. No. 5,958,794 and by Kaisaki et al. in U.S. Pat. No. 6,194,317, incorporated herein by reference. In certain embodiments, a three-dimensional, textured, fixed abrasive article is used. In some embodiments, the abrasive article comprises ceria abrasive particles. In yet further embodiments, the abrasive articles comprise precisely shaped abrasive composites. Exemplary abrasive articles having precisely shaped abrasive composites comprising ceria particles that are useful for the processes of the present disclosure include those commercially obtained from 3M Company, St. Paul, Minn., and marketed under the trade designation “3M SLURRYFREE CMP FIXED ABRASIVE 3152” and “3M SLURRYFREE CMP FIXED ABRASIVE 3154.”

Suitable abrasive articles can be provided in various configurations, including, for example, sheets, webs, rolls, or belts. In these configurations, the abrasive article can be fed linearly into the CMP process during or just prior to polishing operations. In one presently preferred configuration, a fixed abrasive article in web form is mounted in a roll to roll fashion on a carriage such that the web extends across the platen of the CMP machine. During processing, the platen and carriage rotate simultaneously, allowing for rotation of the fixed abrasive article. In this configuration during polishing, the abrasive article is typically held to the platen by vacuum, the platen surface being designed with holes, ports and/or channels to facilitate communication between the vacuum and the abrasive article. Upon completion of the polishing operation, vacuum may be removed and the abrasive web can be moved forward, i.e. incremented a set amount, exposing a fresh region of abrasive on the platen.

In some exemplary embodiments, web increment is preferably less than the width or diameter of the platen, more preferably less than 50 mm, even less than 10 mm and most preferably less than 6 mm. When the abrasive article is in the form of a distinct shape, e.g., a circular disk, it can also be removably mounted to the platen of the CMP machine, e.g., by use of an adhesive, mechanical fasteners including (but not limited) to hook and loop fasteners, magnetic attachments, and the like. Such removably mounted abrasive articles may be particularly suitable for use in a rotary CMP process.

In certain exemplary embodiments, the abrasive article may contain a backing Abrasive particles may be dispersed in a binder to form textured and three-dimensional abrasive composites which are fixed, adhered, or bonded to the backing Optionally, the fixed abrasive article does not have to have a separate backing.

Abrasive articles useful for the method of the present disclosure typically have a diameter or width in the range of about 250 to about 1,000 millimeters (mm). Abrasive articles for use with currently employed 100 to 500 mm diameter wafers will typically have a diameter from about 10 to 200 mm, preferably from about 20 to 150 mm, more preferably from about 25 to 100 mm.

In additional exemplary embodiments, the abrasive article can be selected to be long lasting, e.g., the abrasive article can be selected, at least in part, to polish a minimum number of different wafers. The abrasive article can also be selected based on cut rate. Additionally, the abrasive article can be selected based on its capability of yielding a semiconductor wafer having a desired flatness, surface finish, and minimal dishing. The materials, desired texture, and process used to make the abrasive article can all influence whether or not these criteria are met.

In further exemplary embodiments, a subpad comprising at least one rigid element or rigid segment and/or at least one resilient element, as described in U.S. Pat. Nos. 5,692,950; 6,007,407; 6,632,129; 7,160,178 and 7,163,444, incorporated herein by reference, is interposed between the fixed abrasive and the platen. In some embodiments, the subpad can be mounted to the fixed abrasive, e.g., by use of an adhesive or lamination, prior to mounting the abrasive article to the platen of the CMP machine. When vacuum is used to hold the abrasive article to the platen and a subpad is interposed between the platen and abrasive article, the subpad contains at least one hole, port and/or channel that allows communication between the hole(s), port(s) and/or channel(s) of the platen, enabling the vacuum to hold the abrasive article in position above the platen.

### Working Liquids

During CMP processing using the methods of the present disclosure, a working liquid may be present at the interface between the abrasive article and the wafer. The working liquid in combination with the abrasive article aids polishing through chemical and/or mechanical effects. Typically, during planarization, there is a consistent flow of the working liquid to the interface between the abrasive article and the wafer. The liquid flow rate typically ranges between about 10 to 10,000 milliliters per minute. In some embodiments, the liquid flow rate may be in the range of about 10 to 500 milliliters per minute. In yet further embodiments, the liquid flow rate may be between about 25 to 250 milliliters per minute.

In some exemplary applications, the working liquid typically comprises water, this water can be tap water, distilled water or deionized water. The pH of the working liquid may be advantageously adjusted for particular wafer surface materials and CMP processes. For example, for removal of surface oxide materials at high removal rates according to certain embodiments of the present disclosure, the pH is generally no greater than 7, more preferably less than 6, most preferably less than 5. The lower limit of pH used in removal of surface oxide materials is generally no less than about 2, preferably no less than about 3, and more preferably no less than about 4. Typically the working liquid exhibits a pH within the range from about 2 to 7.

It will be understood by one of ordinary skill in the art that the lower limit of pH that may be used will depend upon the particular CMP equipment and materials and their materials of construction. For example, in certain CMP applications, a pH of 2 may be too low for use without causing damage or corrosion to metals or other materials used in fabricating the CMP equipment and the articles used in the CMP process (e.g. the fixed abrasive article and its mounting components). Therefore, in certain embodiments, a narrower pH range may be preferred, for example, from about 4 to about 6. The pH can be adjusted using methods and solutions known to those skilled in the art, including, for example, the addition of KOH, NaOH, NH₄OH, HCl, HNO₃, H₂SO₄, and/or H₃PO₄. In some embodiments, the working liquid may be buffered.

Exemplary working liquids useful in certain embodiments of the present disclosure comprise an aqueous solution of initial components substantially free of loose abrasive particles, the components including water, a polyelectrolyte, and a surfactant, the working liquid exhibiting a pH from about 2 to 7. In certain embodiments, the working liquid may additionally include an optional complexing agent (e.g. a chemical agent which chelates to, or forms a chemical complex with, another chemical species, for example, a metal ion), which may be an acidic complexing agent.

As noted above, in exemplary embodiments of the present disclosure, the working liquid is substantially free of inorganic particulates, e.g., loose abrasive particles that are not associated with the fixed abrasive article. In some embodiments, the working liquid contains less than 1% by weight, or less than 0.1% by weight of inorganic particulates not associated with the fixed abrasive article.

According to certain embodiments of the present disclosure, the polyelectrolyte may generally selected from a polymer or copolymer of polyacrylic acid, poly(meth)acrylic acid, salts of polyacrylic acid, salts of poly(meth)acrylic acid, and mixtures thereof. In certain exemplary embodiments, the polyelectrolyte exhibits a mean weight average molecular weight (M_{W}) of at least 500 Daltons (Da), more preferably at least about 1,000 Da, even more preferably at least about 2,000 Da, most preferably at least about 5,000 Da. In other exemplary embodiments, the polyelectrolyte exhibits a mean weight average molecular weight (M_{W}) of at most 30,000 Da, more preferably at most about 20,000 Da, even more preferably at most about 15,000 Da, and most preferably at most about 10,000 Da.

In additional exemplary embodiments, the polyelectrolyte may be present in the working liquid in an amount of at least 0.001% w/w, more preferably at least about 0.01% w/w, more preferably at least about 0.025% w/w, and most preferably at least about 0.1% w/w. In other exemplary embodiments, the polyelectrolyte may be present in the working liquid in an amount of at most 5.0% w/w, more preferably at most about 3.0% w/w, more preferably at most about 2.5% w/w.

The surfactant may generally be selected from water soluble surfactants, with nonionic surfactants being preferred. Generally, the nonionic surfactant exhibits a calculated hydrophile-lipophile balance (i.e., HLB), calculated as the weight percent of hydrophile in the surfactant molecule divided by 5, of at least about 4, more preferably at least about 6, even more preferably at least about 8, and most preferably at least about 10. The calculated HLB is generally no greater than 20. In some embodiments, the surfactant is a fluorochemical surfactant, that is, the surfactant molecule comprises one or more fluorine atoms.

The nonionic surfactant may be advantageously selected from a linear primary alcohol ethoxylate, a secondary alcohol ethoxylate, a branched secondary alcohol ethoxylate, an octylphenol ethoxylate, an acetylenic primary alcohol ethoxylate, an acetylenic primary di-alcohol ethoxylate, an alkane di-alcohol, a hydroxyl-terminated ethylene oxide-propylene oxide random copolymer, a fluoroaliphatic polymeric ester, and mixtures thereof.

Generally, the nonionic surfactant may be present in the working liquid in an amount of at least about 0.025% w/w, more preferably at least about 0.05% w/w, even more preferably about 0.1% w/w. The upper limit of surfactant concentration in the working liquid may be generally at most about 1% w/w, more preferably at most about 0.5% w/w, even more preferably at most about 0.2% based on the weight of the working liquid.

In certain presently preferred embodiments, the surfactant may be selected to be a fluorochemical surfactant. In one exemplary embodiment, the working liquid exhibits a pH of 4.5, and comprises a 13,350 Da (M_{W}) fluorochemical surfactant (e.g. L-19909, available from 3M Company, St. Paul, Minn.) at a concentration of 0.5% w/w of the working liquid, and a 10,000 Da (M_{W}) polyacrylic acid polyelectrolyte (e.g. L-19457, available from Polysciences, Inc., Warrington, Pa.) at a concentration of 0.025% w/w of the working liquid. In other exemplary embodiments, the surfactant may be selected to be a nonionic surfactant, and the working liquid additionally includes an optional complexing agent. In such embodiments, the preferred pH may be generally from about 4 to 7.

In further exemplary embodiments, the working liquid comprises an aqueous solution of initial components substantially free of loose abrasive particles, the components including water, a polyelectrolyte, and a surfactant, and the working liquid exhibiting a pH from about 2 to 7. In certain exemplary embodiments, the working liquid is useful in modifying a surface of a wafer suited for fabrication of a semiconductor device, wherein the surfactant is present in an amount effective to obtain an oxide removal rate of at least about 200 angstroms per minute and the polyelectrolyte is present in an amount effective to obtain an oxide to nitride selectivity of at least about 10 when used with a fixed abrasive article for chemical mechanical planarization of a DRAM STI wafer.

In additional exemplary embodiments according to the present disclosure, an optional complexing agent is included in the working liquid. The optional complexing agent is preferably an acidic complexing agent compatible with the acidic pH of the working liquid. Preferably, the acidic complexing agent is a multidentate acidic complexing agent, more preferably at least one of an amino acid or a dipeptide formed from an amino acid. Suitable amino acids include alanine, proline, glycine, histidine, lysine, arginine, ornithene, cysteine, tyrosine, and combinations thereof. A preferred acidic multidentate complexing agent is the amino acid proline, more preferably L-proline.

The acidic complexing agent may be generally present in an amount from about 0.1% w/w (i.e. percent by weight based on the working liquid), more preferably at least about 1% w/w, even more preferably at least about 2% w/w, and most preferably about 2.5% w/w; and generally no more than about 5% w/w, more preferably no more than 4% w/w, and even more preferably less than about 3% w/w based on the weight of the working liquid.

### CMP Methods and Processes

In one exemplary embodiment, the present disclosure provides a method for polishing a wafer by providing a wafer comprising a first region comprising a dielectric material, such as silicon dioxide, and a second region comprising a barrier material, such as silicon nitride, contacting the wafer with a three-dimensional, textured, fixed abrasive article comprising a plurality of abrasive particles and a binder, and relatively moving the wafer and the fixed abrasive article.

In one particular embodiment, the present disclosure provides a method of modifying a surface of a wafer suited for fabrication of a semiconductor device, the method including:
a. providing a wafer comprising at least a first material having a surface etched to form a pattern, a second material deployed over at least a portion of the surface of the first material, and a third material deployed over at least a portion of the surface of the second material;
b. in the presence of a working liquid comprising an aqueous solution of initial components substantially free of loose abrasive particles, the components including water, a polyelectrolyte, and a surfactant, the working liquid exhibiting a pH from about 2 to 7, contacting the third material of the wafer to a plurality of three-dimensional abrasive composites fixed to an abrasive article, the three-dimensional abrasive composites comprising a plurality of abrasive particles fixed and dispersed in a binder; and
c. providing relative motion between the wafer and the abrasive article while the third material is in contact with the plurality of abrasive composites until an exposed surface of the wafer is planar and comprises at least one area of exposed third material and one area of exposed second material.

In one exemplary embodiment, the first material comprises a patterned material, the second material comprises a barrier material, and the third material comprises a dielectric material. In an exemplary presently preferred embodiment, the first material comprises a metal, the second material comprises silicon nitride, and the third material comprises silicon oxide. In further exemplary embodiments, the working liquid comprises an aqueous solution of initial components substantially free of loose abrasive particles, the components including water, a polyelectrolyte, and a surfactant, and the working liquid exhibiting a pH from about 2 to 7. In certain exemplary embodiments, the working liquid is useful in modifying a surface of a wafer suited for fabrication of a semiconductor device, wherein the surfactant is present in an amount effective to obtain an oxide removal rate of at least about 200 angstroms per minute and the polyelectrolyte is present in an amount effective to obtain an oxide to nitride selectivity of at least about 10 when used with a fixed abrasive article for chemical mechanical planarization of a DRAM STI wafer.

In other exemplary embodiments, the present disclosure provides a process for polishing a surface of a wafer suited for fabrication of a semiconductor device, the process including:
a. providing a wafer comprising at least a barrier material deployed over at least a portion of the wafer; and a dielectric material deployed over at least a portion of the barrier material;
b. in the presence of an aqueous working liquid substantially free of loose abrasive particles and including water, a polyelectrolyte and a surfactant, the working liquid exhibiting a pH from about 2 to 7, contacting the dielectric material of the wafer to a plurality of three-dimensional abrasive composites fixed to an abrasive article, the three-dimensional abrasive composites comprising a plurality of abrasive particles fixed and dispersed in a binder; and
c. providing relative motion between the wafer and the abrasive article while the dielectric material is in contact with the plurality of abrasive composites until an exposed surface of the wafer is planar and comprises at least one area of exposed dielectric material and one area of exposed barrier material.

In certain exemplary presently preferred embodiments, the barrier material comprises silicon nitride, and the dielectric material comprises silicon oxide. In further exemplary embodiments, the working liquid comprises an aqueous solution of initial components substantially free of loose abrasive particles, the components including water, a polyelectrolyte, and a surfactant, and the working liquid exhibiting a pH from about 2 to 7. In certain exemplary embodiments, the working liquid is useful in modifying a surface of a wafer suited for fabrication of a semiconductor device, wherein the surfactant is present in an amount effective to obtain an oxide removal rate of at least about 200 angstroms per minute and the polyelectrolyte is present in an amount effective to obtain an oxide to nitride selectivity of at least about 10 when used with a fixed abrasive article for chemical mechanical planarization of a DRAM STI wafer.

Processing parameters for the exemplary methods and processes of the present disclosure can be selected to achieve desired removal rates and/or selectivity by the skilled person guided by this disclosure. For example, the composition, concentration, and the pH of the working liquid can be adjusted to control the removal rate of the dielectric material. In some embodiments, the composition is modified to control the removal rate of the dielectric material or the mask layer. In order to determine the concentration of a composition for the desired rate of removal or selectivity, a series of at least two working liquids having differing concentrations can be tested to determine the optimal concentration. Likewise, to determine the working liquid pH for the desired rate of removal or selectivity, a series of at least two working liquids having differing pH levels can be tested to determine the optimal pH level.

For example, in some exemplary embodiments, the working liquid may be selected to have a dielectric removal rate of at least about 200 angstroms per minute. In other embodiments, the working liquid may be selected to have a dielectric removal rate of at least 500 angstroms per minute. In other embodiments, the working liquid may be selected to have a dielectric removal rate of at least 1,000 angstroms per minute. In other embodiments, the working liquid may be selected to have a dielectric removal rate of at least 1,500 angstroms per minute. In yet further embodiments, the working liquid may be selected to have a dielectric removal rate of at least 2,000 angstroms per minute.

In further exemplary embodiments, the working liquid may be selected to have a silicon nitride removal rate no greater than about 100 angstroms per minute. In other embodiments, the working liquid may be selected to have a silicon nitride removal rate no greater than 50 angstroms per minute. In further embodiments, the working liquid may be selected to have a nitride removal rate no greater than 30 angstroms per minute. In yet further embodiments, the working liquid is selected to have a nitride removal rate no greater than 10 angstroms per minute.

The ratio of the dielectric removal rate to the barrier removal rate may be used to determine a selectivity ratio for the CMP process, that is, the dielectric to barrier layer selectivity. In certain exemplary embodiments, the working liquid is selected to have a dielectric to barrier layer selectivity of at least 10. In other embodiments, the working liquid is selected to have a dielectric to barrier layer selectivity of at least 50. In other embodiments, the working liquid is selected to have a dielectric to barrier layer selectivity of at least 100. In yet further embodiments, the working liquid is selected to have a dielectric to barrier layer selectivity of at least about 150.

The amount of the working liquid is preferably sufficient to aid in the removal of dielectric and other deposited material from the wafer surface. In many instances, there is sufficient liquid from the basic working liquid. However, in some instances it is preferred to have a second liquid present at the planarization interface in addition to the first working liquid. This second liquid may be the same as the liquid from the first liquid, or it may be different.

### EXAMPLES

Advantages and other embodiments of this disclosure are further illustrated by the following examples, but the particular materials and amounts thereof recited in these examples, as well as other conditions and details, should not be construed to unduly limit this invention. For example, composition and concentration of the working liquid can be varied. All parts and percentages are by weight unless otherwise indicated. The material designations shown in TABLE 1 are used throughout the examples.

TABLE 1

| Designation | Material |
|---|---|
| Dynol 607 | Acetylenic di-alcohol ethoxylate surfactant |
| | exhibiting an HLB of 8, available from Air |
| | Products & Chemicals, Inc., Allentown, PA |
| L-19455 | Sodium salt of polymethacrylic acid (poly- |
| | electrolyte) having a weight average molecular |
| | weight between 15,000 and 30,000 Daltons, |
| | available from 3M Company, St. Paul, MN |
| L-19457 | Polyacrylic acid (polyelectrolyte) having a |
| | mean weight average molecular weight of 10,000 |
| | Da, available from Polysciences, Inc., |
| | Warrington, PA |
| L-19909 | Fluorochemical surfactant exhibiting an HLB of |
| | 12, supplied as a solution of 85-95% w/w fluoro- |
| | aliphatic polymeric esters and 5-10% w/w polyether |
| | polymer in <2% 1-methyl-2-pyrrolidinone/toluene/2- |
| | propenoic acid blend, available from 3M Company, |
| | St. Paul, MN |
| PAA-1 | Polyacrylic acid (polyelectrolyte) having a mean |
| | weight average molecular weight of 2,000 Da, |
| | available from Polysciences, Inc., Warrington, PA |

### Evaluation of Working Liquids

A series of experiments was carried out to evaluate various working liquids useful in modifying a surface of a wafer suited for fabrication of a semiconductor device. In exemplary embodiments, a surfactant was used in conjunction with a polyelectrolyte in various working liquids useful in modifying a surface of a wafer suited for fabrication of a semiconductor device. The working liquids were aqueous solutions of initial components substantially free of loose abrasive particles and exhibiting a pH from about 2 to about 7, the components comprising water, a surfactant, and a polyelectrolyte.

The surfactant and polyelectrolyte containing working liquids were evaluated for their ability to accelerate or maintain the oxide removal rate in a stop-on-nitride CMP process using a fixed abrasive web. As comparative examples, control working liquids with pH 7 or greater, comprising water, an acidic complexing agent (e.g. L-proline), a basic pH adjusting agent (e.g. ammonium hydroxide), and optionally, a fluorochemical surfactant, were also evaluated.

Unless otherwise stated, all experiments were conducted using a 3M SWR550 fixed abrasive web (3M Company, St. Paul, Minn.) and a 60/90 ribbed subpad (3M Company, St. Paul, Minn.) on a Reflexion™ polisher (Applied Materials, Inc., Santa Clara, Calif.) mounted with a Contour 200 mm carrier. The membrane pressure was set at 3 psi (about 20.7 kPa). For Examples 3-7 and Comparative Example I-L, a 60/90 smooth subpad was used and the membrane pressure was set at 2 psi (13.8 kPa). The carrier and platen rotational speeds were 28 and 30 RPM, respectively. A 5 millimeter (mm) increment was employed and 100 ml of working liquid per minute was applied to the fixed abrasive web surface.

Blanket tetraethyl orthosilicate (TEOS) wafers (having a silicon oxide dielectric material deployed over the wafer surface), and cleared 0.17 μm DRAM STI wafers (having a silicon nitride barrier coating deployed over at least a portion of the patterned wafer surface, and a silicon oxide dielectric coating deployed over at least a portion of the silicon nitride barrier coating), both 200 mm in diameter, were polished. A DRAM STI wafer was used for Examples 1-2 and Comparative Examples B, F, G and I-L. Polishing time was one minute for blanket TEOS wafers and 30 s for the DRAM STI wafers. The polishing rate for the silicon oxide and the silicon nitride wafers was determined by measuring the film thickness before and after polishing using a Thermawave Optiprobe™ 2600 (available from KLA Tencor Corp., Fremont, Calif.). The silicon oxide wafers were measured with a 21 point area scan. 0.17 um DRAM STI wafers were used for determining the nitride polishing rate and were measured with a 13 point template, distributed evening about the wafer surface.

A control working liquid comprising 2.5% w/w L-Proline at pH 10.5 was first run, followed by 0.05% w/w L-19909 fluorochemical surfactant in deionized DI water, first at pH 7, and subsequently at a pH of 4.75. Two different polyelectrolytes were then evaluated: L-19455 and L-19457. Each polyelectrolyte was evaluated at 2.5% w/w of the working liquid in the presence of a surfactant. In Comparative Examples J-L, the molecular weight of the fluorinated surfactant was varied by varying the mean weight average molecular weight of the nonfluorinated precursor nonionic surfactant, PLURONIC™ XX (available from BASF Corporation, Wyandotte, Mich.), prior to fluorination. It will understood by those possessing ordinary skill in the art that such methods may be used to vary the molecular weight of the surfactant to vary the rate of oxide (e.g. silica) removal from a wafer surface when the fluorinated surfactant is combined with a polyelectrolyte to obtain the desired nitride removal rate and selectivity. The results for working fluids using both a surfactant and a polyelectrolyte are summarized in TABLE 2.

TABLE 2

| | | | | Oxide | Nitride | |
|---|---|---|---|---|---|---|
| | | Complexing | | Removal | Removal | |
| | | Agent or | | Rate | Rate | |
| Example | Surfactant | Polyelectrolyte | pH | (Å/min.) | (Å/min.) | Selectivity |
| Comparative | None | None | 10.5 | 113 | — | — |
| A (Control) | | | | | | |
| Comparative B | None | 2.5% L-proline | 10.5 | 275 | 24 | 11.5 |
| Comparative C | 0.05% w/w | None | 10.5 | 649 | — | — |
| | L-19909 | | | | | |
| Comparative D | 0.05% w/w | 2.5% L-proline | 10.5 | 2,260 | — | — |
| | L-19909 | | | | | |
| Comparative E | None | None | 7.0 | 68 | — | — |
| 1 | 0.05% w/w | 2.5% w/w | 7.0 | 306 | 0 | Infinite |
| | Dynol 607 | L-19457 | | | | |
| Comparative F | 0.05% w/w | None | 7.0 | 308 | 90 | 3.4 |
| | L-19909 | | | | | |
| 2 | 0.05% w/w | 2.5% w/w | 7.0 | 591 | 10 | 59.1 |
| | L-19909 | L-19455 | | | | |
| Comparative G | 0.05% w/w | None | 4.75 | 362 | 166 | 2.2 |
| | L-19909 | | | | | |
| Comparative H | None | None | 4.5 | 0 | — | — |
| Comparative I | 0.5% w/w | None | 4.5 | 925 | 148 | 6.3 |
| | L-19909 | | | | | |
| 3 | 0.5% w/w | 0.001% w/w | 4.5 | 930 | 80 | 11.6 |
| | L-19909 | PAA-1 | | | | |
| 4 | 0.5% w/w | 0.005% w/w | 4.5 | 989 | 44 | 22.5 |
| | L-19909 | PAA-1 | | | | |
| 5 | 0.2% w/w | 0.025% w/w | 4.5 | 246 | 0 | Infinite |
| | L-19909; | L-19457 | | | | |
| | Mean | | | | | |
| | M_{w} = 13,350 | | | | | |
| 6 | 0.5% w/w | 0.025% w/w | 4.5 | 520 | 4 | 130.0 |
| | L-19909; | L-19457 | | | | |
| | Mean | | | | | |
| | M_{w} = 13,350 | | | | | |
| 7 | 0.2% w/w | 0.025% w/w | 3.5 | 243 | 2 | 121.5 |
| | L-19909; | L-19457 | | | | |
| | Mean | | | | | |
| | M_{w} = 13,350 | | | | | |
| Comparative J | 0.2% w/w | None | 4.5 | 497 | 36 | 13.8 |
| | L-19909; | | | | | |
| | Mean | | | | | |
| | M_{w} = 13,350 | | | | | |
| Comparative K | 0.2% w/w | None | 4.5 | 881 | 42 | 21.0 |
| | L-19909; | | | | | |
| | Mean | | | | | |
| | M_{w} = 18,990 | | | | | |
| Comparative L | 0.2% w/w | None | 4.5 | 1065 | 60 | 17.8 |
| | L-19909; | | | | | |
| | Mean | | | | | |
| | M_{w} = 34,370 | | | | | |

In one particular embodiment, a non-ionic surfactant (Dynol 607) was added to a 2.5% polymethylacrylic acid (L-19457) aqueous solution and adjusted to pH=7. Increased oxide removal rate was observed with a very low silicon nitride removal rate, i.e., high oxide/nitride selectivity. The 0.05% L-19909 fluorochemical surfactant also appears to allow relatively high polishing rates at pH 7, 4.75 and 4.5. At these pH values, the L-19909 fluorochemical surfactant alone appears to yield relatively low oxide/nitride selectivity. The addition of a polyelectrolyte (e.g. 2.5% w/w L-19455 or 0.005% PAA-1) causes the nitride rate to drop significantly, yielding improved oxide/nitride selectivity.

In some exemplary embodiments, the advantages of using an acidic or neutral pH (e.g. pH=2-7) in a CMP process may include, for example, the ability to obtain higher oxide removal rates while maintaining stop on nitride selectivity. In other exemplary embodiments, the advantages of using an acidic or neutral pH in a CMP process may include the ability to use lower polishing pressure on the wafer and thereby reduce defects and increase yield while maintaining good polishing rate. In further exemplary embodiments, the advantages of using an acidic or neutral pH in a CMP process may include the ability to obtain a harder oxide surface that may be less susceptible to scratching.

In addition, in certain exemplary embodiments, use of an acidic pH in combination with a surfactant may enable high rate polishing when used with alternative stop on nitride chemistries based on polyelectrolytes. Such alternative stop on nitride chemistries may also result in greater selectivity relative to chemistries using multidentate complexing agents such as amino acids under highly alkaline conditions (e.g. pH 9-11). Such alternative stop on nitride chemistries may be particularly well suited for Shallow Trench Isolation, where it is desirable to maintain a high selectivity between oxide and nitride removal rate.

In additional exemplary embodiments, the low dishing obtained in CMP using a fixed abrasive may substantially reduce the risk of wafer dishing in a highly selective STI process carried using an acidic working liquid including a surfactant and a polyelectrolyte. For example, use of the L-19909 surfactant may permit use of fixed abrasives to obtain higher oxide removal rates under acidic conditions while still allowing the polyelectrolyte to selectively stop-on-nitride. This may provide a substantial advantage for use of fixed abrasives over the conventional slurry process in STI CMP, because in the slurry process, as the slurry begins to clear to the nitride, it continues to polish the oxide in the trench areas, causing dishing of the surface. Dishing is a very significant draw-back to the slurry process. Use of fixed abrasives may produce at least an order of magnitude less dishing as compared to the slurry process.

It is to be understood that even in the numerous characteristics and advantages of the present disclosure set forth in above description and examples, together with details of the structure and function of the disclosure, the disclosure is illustrative only. Changes can be made to detail, especially in matters of the composition and concentration of the working liquid and methods of use within the principles of the disclosure to the full extent indicated by the meaning of the terms in which the appended claims are expressed and the equivalents of those structures and methods.

It is apparent to those skilled in the art from the above description that various modifications can be made without departing from the scope and principles of this disclosure, and it should be understood that this disclosure is not to be unduly limited to the illustrative embodiments set forth hereinabove. Various embodiments of the disclosure have been described. These and other embodiments are within the scope of the following claims.

What is claimed is:

1. A working liquid useful in modifying a surface of a wafer suited for fabrication of a semiconductor device, the liquid being an aqueous solution of initial components substantially free of loose abrasive particles, the components comprising:
a. water;
b. a polyelectrolyte; and
c. a surfactant,
wherein the working liquid exhibits a pH from 3 to 7.

2. The working liquid of claim 1, further comprising a complexing agent.

3. The working liquid of claim 2, wherein the complexing agent comprises a multidentate acidic complexing agent.

4. The working liquid of claim 3 wherein the multidentate acidic complexing agent comprises at least one of an amino acid or a dipeptide formed from an amino acid.

5. The working liquid of claim 4, wherein the amino acid is selected from alanine, proline, glycine, histidine, lysine, arginine, ornithene, cysteine, tyrosine, and combinations thereof.

6. The working liquid of claim 5, wherein the amino acid is L-proline.

7. The working liquid of claim 2, wherein the multidentate acidic complexing agent is present in an amount from 0.1% by weight to 5% by weight of the working liquid.

8. The working liquid of claim 1, wherein the surfactant is a nonionic surfactant.

9. The working liquid of claim 8, wherein the nonionic surfactant exhibits a hydrophile-lipophile balance (HLB) of at least 8.

10. The working liquid of claim 8, wherein the nonionic surfactant is selected from an acetylenic primary alcohol ethoxylate, an acetylenic primary di-alcohol ethoxylate, a fluoroaliphatic polymeric ester, and mixtures thereof.

11. The working liquid of claim 8, wherein the nonionic surfactant is present in an amount of at least 0.025% and at most 0.5% by weight of the working liquid.

12. The working liquid of claim 1, wherein the polyelectrolyte is selected from the group consisting of polyacrylic acid, poly(meth)acrylic acid, salts of polyacrylic acid, salts of poly(meth)acrylic acid, and mixtures thereof.

13. The working liquid of claim 1, wherein the polyelectrolyte exhibits a weight average molecular weight from 1,000 to 30,000 Da.

14. The working liquid of claim 1, wherein the polyelectrolyte is present in an amount from 0.001% to 5.0% by weight of the working liquid.

15. The working liquid of claim 1, wherein the working liquid exhibits a pH from 4 to 7.

16. The working liquid of claim 1, wherein the surfactant is present in an amount effective to obtain an oxide removal rate of at least 200 angstroms per minute and the polyelectrolyte is present in an amount effective to obtain an oxide to nitride selectivity of at least 10 when used with a fixed abrasive article for chemical mechanical planarization of a shallow trench isolation (STI) wafer.

17. A method of modifying a surface of a wafer suited for fabrication of a semiconductor device comprising:
a. providing a wafer comprising at least a first material having a surface etched to form a pattern, a second material deployed over at least a portion of the surface of the first material, and a third material deployed over at least a portion of the surface of the second material;
b. in the presence of a working liquid according to claim 1, contacting the third material of the wafer to a plurality of three-dimensional abrasive composites fixed to an abrasive article, the three-dimensional abrasive composites comprising a plurality of abrasive particles fixed and dispersed in a binder; and
c. providing relative motion between the wafer and the abrasive article while the third material is in contact with the plurality of abrasive composites until an exposed surface of the wafer is planar and comprises at least one area of exposed third material and one area of exposed second material.

18. A process for polishing a surface of a wafer suited for fabrication of a semiconductor device, comprising:
a. providing a wafer comprising a barrier material deployed over at least a portion of the wafer; and a dielectric material deployed over at least a portion of the barrier material;
b. in the presence of an aqueous working liquid substantially free of loose abrasive particles and including water, a polyelectrolyte and a surfactant, the working liquid exhibiting a pH from 3 to 7, contacting the dielectric material of the wafer to a plurality of three-dimensional abrasive composites fixed to an abrasive article, the three-dimensional abrasive composites comprising a plurality of abrasive particles fixed and dispersed in a binder; and
c. providing relative motion between the wafer and the abrasive article while the dielectric material is in contact with the plurality of abrasive composites until an exposed surface of the wafer is planar and comprises at least one area of exposed dielectric material and at least one area of exposed barrier material.

19. The process of claim 18, wherein the barrier material comprises silicon nitride, and the dielectric material comprises silicon oxide.

20. The process of claim 19 wherein said polishing comprises a silicon dioxide removal rate of at least about 200 angstroms per minute.

21. The process of claim 19 wherein said polishing comprises a silicon nitride removal rate of no more than about 100 angstroms per minute.

22. The process of claim 19 wherein said polishing comprises a silicon dioxide to silicon nitride selectivity of at least about 10.

23. A working liquid useful in modifying a surface of a wafer suited for fabrication of a semiconductor device, the liquid being an aqueous solution of initial components substantially free of loose abrasive particles, the components comprising:
a. water;
b. a polyelectrolyte; and
c. a nonionic surfactant,
wherein the working liquid exhibits a pH from about 2 to 7, and wherein the nonionic surfactant is present in an amount effective to obtain an oxide removal rate of at least about 200 angstroms per minute and the polyelectrolyte is present in an amount effective to obtain an oxide to nitride selectivity of at least about 10 when used with a fixed abrasive article for chemical mechanical planarization of a shallow trench isolation (STI) wafer.
